(19) United States
(12) Patent Application Publication
(10) Pub. No.: US 2009/0302777 A1
(43) Pub. Date: Dec. 10, 2009

(54) PULSE GENERATOR USED FOR ELECTRONIC BALLAST

(75) Inventors: Dongli Li, Shanghai (CN); Zhong Chen, Shanghai (CN); Tjaco Middel, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/158,717

(22) PCT Filed: Dec. 29, 2006
(86) PCT No.: PCT/IB2006/003795

§ 371 Date: Feb. 21, 2009

(30) Foreign Application Priority Data
Dec. 29, 2005 (CN) 200520038163.5

(51) Int. Cl. H05B 41/30; H03K 3/00

(52) U.S. Cl. 315/287; 327/291

(57) ABSTRACT

The present utility model proposes an impulse generator for driving an electronic ballast of a gas discharge lamp, the electronic ballast includes a resonance ignition circuit, characterized in that the impulse generator comprises: a micro-controller for generating a clock frequency signal, a logical time sequence control signal and a control voltage signal; a voltage controlled oscillator, coupled to the micro-controller, for receiving the logical time sequence control signal and the control voltage signal to generate oscillation and output a voltage controlled oscillating frequency signal; a phase comparator for receiving the clock frequency signal and the voltage controlled oscillating frequency signal to perform a logical exclusive-OR operation and output an impulse signal of corresponding frequency, thereby driving the resonance ignition circuit to generate a resonance voltage. In addition, the utility model also proposes an over-voltage protection circuit used for the electronic ballast.

### FIELD OF THE UTILITY MODEL

The present utility model relates to a UHP (ultrahigh-pressure) lamp or HID (high, intensive discharge) lamp, an electronic ballast used by the UHP or HID lamp and a pulse generator used for the electronic ballast.

### BACKGROUND OF THE UTILITY MODEL

FIG. 1a is a functional block diagram of an electronic ballast of a UHP or HID lamp in the prior art, and FIG. 1b is a circuit schematic diagram of said electronic ballast in the prior art. The circuit of the electronic ballast in the prior art will be explained in conjunction with FIGS. 1a and 1b.

A main circuit topology of the circuit consists of a M-bridge converter (including MOSFET, namely Metallic Oxide Semiconductor Field Effect Transistors Q3, Q4, Q5 and Q6) and a LC serial resonant circuit (including an inductor L1 and high-pressure serial capacitors C6, C7 and C8). During operation, two ends (4) and (5) of the bridge circuit are inputted with a DC busbar voltage, and Q3 (Q6) and Q5 (Q4) are switched on alternately to convert the DC busbar voltage into an alternate square wave. A high voltage generated by serial resonant is applied to two ends (9) and (10) of a lamp tube T1 to ignite the lamp. A cloak signal of a full-bridge driving circuit is supplied by a voltage controlled oscillator (VCO) based on IC chip TS555. As shown in FIG. 1b, pin OUT of a chip U1 outputs the clock signal to be delivered to the full-bridge driving circuit, which clock signal is then frequency-divided into four paths and output to the full-bridge circuit.

The circuit of an existing 555 pulse generator is as shown by the dashed-line block diagram in FIG. 1b. An integrated timer chip U1 and circumjacent RCD elements (including R2, R3, R4, C1, C2, C3, C10 and D2) form a typical 555 free-running multivibrator serving as a pulse clock source for the full-bridge driving circuit. A +5 power supply charges C2 through R4 and D2 and the C2 discharges through R3 and a chip built-in discharge tube of U1, C1 can be regarded as a voltage source controlled by DAC of a microcontroller U4, which amplitude controllable voltage source, through R2 and D2, charges C2 together with the +5V power supply. And the control of the 555 VCO clock pulse frequency is implemented through controlling, by DAC, voltage amplitude of the two ends of C1. This is the basic operating principle of the 555 pulse generator. C3 is connected between a control voltage point 5 (CV) and the ground to eliminate high-frequency interference and to guarantee a stable voltage on this point. C10 is a decoupling capacitor.

A comparator U3 and resistors R14, R15 and R13 form a resonant voltage detecting circuit R14 and R15 supply a voltage reference, a resonant voltage can be set by adjusting the voltage reference. A sampling signal of the resonant voltage on the two ends (9) and (10) of the high voltage capacitors (C6, C7 and C8) is obtained via a resonant voltage sampling circuit, and this sampling signal is delivered to the negative input terminal (8) of comparators U3 and U2 (the negative input terminals of U2 and U3 are connected together directly). C5 filters the sampling signal.

Built-in DAC of the microcontroller U4 gradually decreases from +5V, the frequency of a pulse clock at point (3) also decreases gradually (called as a scanning frequency procedure). At this time, if the tube T1 is not broken down (corresponding to no-load), the resonant voltage on the two ends (9) and (10) of the tube T1 gradually increases with the decrease of the clock frequency. When the resonant voltage increases to a set value, an output terminal (1) of the comparator U3 outputs a low level. After the microcontroller U4 detects a low level transition signal, the output level of DAC is kept constant, and the frequency of the pulse clock at the point (3) becomes constant correspondingly (the scanning frequency procedure ends). At this time, the LC serial resonant circuit oscillates under a constant frequency. Theoretically, in the case of no-load, the resonant voltage generated by the resonant circuit at this time should also be constant.

However, since the output pulse clock frequency of the existing 555 pulse generator is poor in stability, the resonant voltage generated by the resonant circuit is unstable. A waveform of the existing resonant voltage is as shown in FIG. 2. In FIG. 2, curve 1 is a resonant voltage between the two ends (9) and (10) of the tuba T1, and curve 2 is the amplified resonant voltage waveform thereof.

There are also other types or models of IC chips. For example, MC14046 is an integrated phase-looked loop chip, and currently there is a good many of brands of such chip on market, such as MC14046 series (MC14046B and MC14046BDWR2G) by ON Semiconductor and MC14046 series by MOTOROLA, with a similar structure and totally the same function. Now, take MC14046B as an example, whose functional principle block diagram is as shown in FIG. 5.

The function of each lead-out terminal of this chip is explained as follows: LD: a phase difference signal output terminal of phase comparator 2 output terminal, which is high level when the loop is looked, low level when the loop is unlocked, and triggered at rising edge. PC2ₒᵤₜ: an output terminal of the phase comparator 2, which is a tristate phase difference signal and triggered at rising edge. VCOᵢₙ: an input signal of the voltage controlled oscillator. VCOₒᵤₜ: an output of the voltage controlled oscillator. PCBᵢₙ and PCAᵢₙ; input signals of two phase comparators, INH: an inhibiting terminal, which inhibits the voltage controlled oscillator from operating at high level and allows the voltage controlled oscillator to operate at low level. C1_{A} and C1_{B} pins: to connect external oscillating capacitors, R1 and R2 pins: to connect external oscillating resistors. V_{DD}: positive power supply; V_{SS}: ground. ZENER pin: to connect cathode of internal independent Zener diode. And SFₒᵤₜ: an output of source follower.

The most typical application of MC14046 is phase lock. FIGS. 6a and 6b are a traditional functional block diagram and an application waveform view (take the application of phase comparator 1 as on example) of MC14046 serving as a phase-locked loop. An input signal is amplified and shaped and then applied to an input terminal PCAᵢₙ of the phase comparator 1. An output signal PC1ₒᵤₜ (digital phase error signal) of the phase comparator 1 is the result of exclusive-OR logic operation of the input signals PCAᵢₙ and PCBᵢₙ. An externally-connected low-pass filter acts on PC1ₒᵤₜ to obtain a voltage controlled signal VCOᵢₙ which is applied to an input terminal of the voltage controlled oscillator VCO so as to adjust output frequency VCOₒᵤₜ of VCO. VCOₒᵤₜ is frequency-divided by an eternal frequency divider and then connected to input terminal PCBᵢₙ of phase comparator 1. Having been adjusted for a certain time of period, PCBᵢₙ approaches PCAᵢₙ, and the phase of pulse clock PC1ₒᵤₜ is locked,

A common problem in the above prior arts is that VCO output frequency is not stable, Thus, the resonant voltage is not stable, which, in turn, results in bad stability of ignition of the UHP or HID lamp and susceptibility to extinction of the UHP or HID lamp. Consequently, the lamp's ignition and use effect are severely impacted. Additionally, a too low pulse clock due to VCO frequency drift will cause the full-bridge converter to enter a capacitive operating mode, which reduces the operation reliability of the resonant circuit.

### SUMMARY OF THE UTILITY MODEL

It is an object of the present utility model to provide a pulse generator, which can provide a stable pulse output, used for an electronic ballast of a UHP and HID lamp and an electronic ballast including the pulse generator.

Based on the aforesaid object, the present utility model proposes a pulse generator used for an electronic ballast of a gas discharge lamp, said electronic ballast including a resonant circuit, characterized in that the pulse generator comprises:
a microcontroller for generating a clock frequency signal, a logic time sequence control signal and a control voltage signal;
a voltage controlled oscillator, coupled to the microcontroller, for receiving said logic time sequence control signal and said control voltage signal to generate and output a voltage controlled oscillating frequency signal; and
a phase comparator, coupled to the voltage controlled oscillator, for receiving said clock frequency signal and said voltage controlled oscillating frequency signal, performing a logic exclusive-OR operation and outputting a pulse signal of corresponding frequency to drive said resonant ignition circuit to generate resonant voltage,

According to another aspect of the present utility model, the present utility model proposes an electronic ballast comprising the aforesaid pulse generator.

According to a further aspect of the present utility model, the present utility model proposes an electronic ballast comprising the aforesaid pulse generator and further comprising:
a full-bridge driving circuit, coupled to the pulse generator, in order to output a driving signal in accordance with said pulse clock signal;
a full-bridge converter, coupled to the full-bridge driving circuit, in order to convert a DC busbar voltage into a positive-negative alternate square wave voltage output in accordance with said driving signal;
a LC serial resonant circuit, coupled to the full-bridge converter, in order to generate a resonant voltage applied to a load (T1) by utilizing high-frequency resonance in accordance with said alternate square wave voltage;
a resonant voltage sampling circuit, coupled to the LC serial resonant circuit, for sampling said resonant voltage;
an over-voltage protective circuit, coupled to the resonant voltage sampling circuit and the pulse

generator, for providing over-voltage protection for fee resonant voltage; and
a resonant voltage detecting circuit, coupled to the resonant voltage sampling circuit, the over-voltage protective circuit and the pulse generator, for detecting, during a spanning frequency procedure of said pulse clock signal, whether or not said resonant voltage reaches a set value;
characterized in that said over-voltage protective circuit comprises:
a voltage comparator whose positive input terminal is connected with a voltage reference of a specific value and whose negative input terminal is connected with a sampling voltage which is connected with said resonant voltage sampling circuit and varies in direct proportion to the circuit's resonant voltage, and outputs a reference signal, for adjusting the resonant voltage in accordance with the reference signal; and
a diode whose anode is connected with the positive input terminal of said voltage comparator and whose cathode is connected via a resistor with the output terminal of said voltage comparator, for forming a positive feedback function on said voltage comparator.

Normally, a phase-locked loop IC chip (e.g, MC14046B) is used as the phase-locked loop IC, whose internal phase comparator 1 is usually used for generating a digital phase error signal. However, in the present utility model, the internal VCO circuit and phase comparator are used separately. On one hand, the internal VCO is used for providing resonant frequency; on the other hand, the phase comparator 1 is used for changing frequencies during different phases.

When used for an electronic ballast, the pulse generator of the present utility model can first provide a voltage controlled oscillator with stable output frequency to improve the stability of an ignition voltage, and can also provide fast and self-lock over-voltage protective means. In addition to the significant improvement of performance, the pulse generator of the present utility model and the electronic ballast based on the pulse generator are of a simple structure, boast a cheap hardware cost and have strong engineering practical applicability

Therefore, the present utility model provides an electronic ballast with a simple structure, low cost and excellent performance. Compared with the existing electronic ballast solution, the technical solution provided by the present utility model greatly improves the stability of the ignition voltage and accomplishes a fast and self-look over-ignition voltage protection function. The novel features of the present utility model are mainly reflected in the following two aspects: first, the present utility model makes full use of internal hardware resources of the traditional integrated phase-locked loop circuit chip in a novel manner and transits the frequencies of the full-bridge driving dock signal at different phases without increasing any additional external logical gate; second, the present utility model achieve self lock of the high ignition voltage protective state by designing a large hysteresis voltage used for the comparator.

### BRIEF DESCRIPTION ON THE DRAWINGS

FIG. 1a is a functional block diagram of an electronic ballast in the prior art;

FIG. 1b is a circuit schematic diagram of an electronic ballast in the prior art;

FIG. 2 is an unstable ignition voltage waveform view of an electronic ballast based on the prior art;

FIG. 3 is a relevant voltage waveform view under over-voltage protection in the prior art;

FIG. 4 is a waveform view of over-high ignition voltage occurring repeatedly without self-lock over-voltage protection in the prior art;

FIG. 5 is a functional block diagram of a MC14046 chip;

FIG. 6a is a functional block diagram of the traditional phase-locked loop application of MC14046;

FIG. 6b is a waveform view of the traditional phase-looked loop application of MC14046;

FIG. 7a is a principle block diagram of an electronic ballast based on a pulse generator of the present utility model;

FIG. 7b is a relevant logical waveform view of a pulse generator of the present utility model;

FIG. 8 is a circuit schematic diagram of an electronic ballast using a pulse generator of the present utility model;

FIG. 9 is a stable ignition voltage waveform view of the present utility model;

FIG. 10 is an ignition voltage waveform view under an over-voltage protection action of the present utility model; and

FIG. 11 is a relevant voltage waveform view under an over-voltage protection action of the present utility model.

### DESCRIPTION OF THE PREFERRED EMBODIMENTS

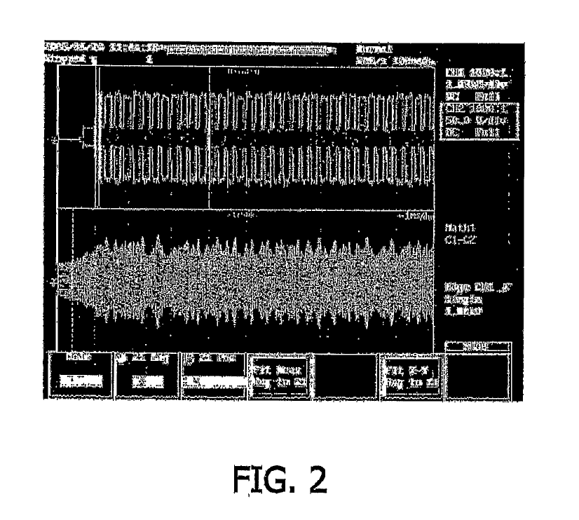

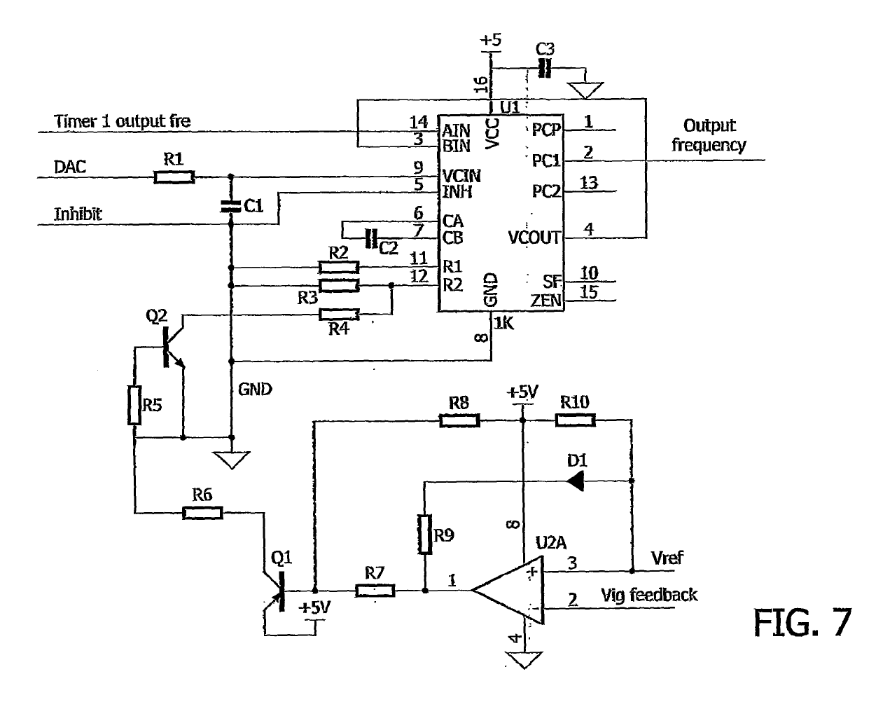

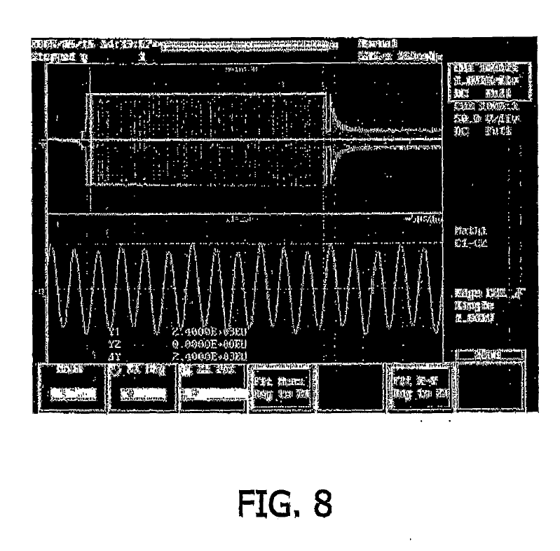

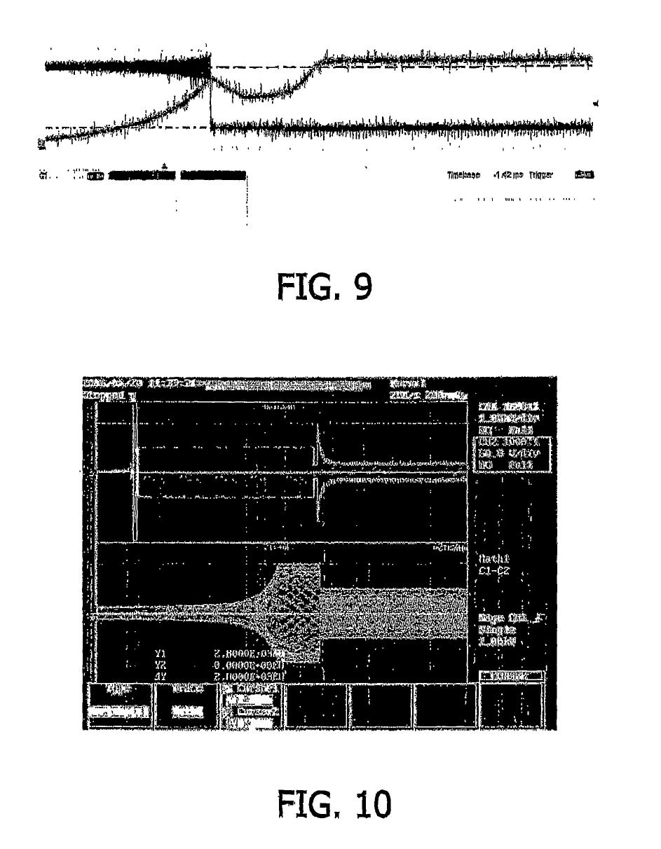

The present utility model is a new application developed from phase-looked loop IC chip (e.g, MC14046), whose functional principle block diagram is as shown in FIG. 7a, and whose concrete circuit is as shown in FIG. 8. FIG. 9 is a waveform view of stable ignition voltage of the present utility model, in which waveform 1 is stable ignition voltage and waveform 2 is an amplified result thereof. As is clear by comparing FIG. 2 with FIG. 9, the improved resonant ignition means greatly improves the stability of the ignition voltage waveform.

As shown in FIGS. 7a and 8, an electronic ballast comprises the following portions:
1) a full-bridge converter (including Q3, Q4, Q5 and Q6) for converting a DC busbar voltage into an alternate square wave;
2) a full-bridge driving circuit for providing MOSFET transistors Q3, Q4, Q5, and Q6 with a gate driving signal;
3) a LC serial resonant circuit (including L1, C6, C7 and C8) for generating a high ignition voltage by utilizing high-frequency resonance technology;
4) a resonant voltage sampling circuit for sampling the resonant voltage on two ends of tube T1;
5) a resonant voltage detecting circuit (including U3, resistors R13, R14, R15 and R16) for detecting, during a scanning frequency procedure, whether or not the resonant voltage reaches a set value, wherein R16 is used for constituting positive feedback from an output terminal of U3 to an input terminal thereof in order to generate a voltage reference hysteresis window of the positive input terminal of U3;
6) a resonant voltage over-voltage protective circuit (including U2, R4, R5, R7, R8, R9, R10, R11, R12, C4, D1, Q1 and Q2) for providing a fast and self-lock over-voltage protection function;
7) a 4046 voltage controlled oscillator (including an integrated phase-locked loop chip U1 and a resistor capacitor network formed by R2, R3, C2 and C3) for providing a pulse clock needed for full-bridge driving;
8) a microcontroller U4 for providing logical time sequence control needed for a voltage controlled oscillator circuit;
9) a positive follower U5, coupled with an analog-to-digital converter output terminal DAC0 of the microcontroller and directly (or via a low-pass filter) coupled to a voltage controlled oscillator input terminal VCOᵢₙ of the integrated phase-locked loop chip, for providing it with a microcontroller signal to improve the driving capability.

Said low-pass filter which comprises R1 and C1 is used for filtering high-frequency noises from the signal.

The microcontroller U4, the positive follower U5, the low-pass filter and the 4046 voltage controlled oscillator (including an integrated phase-locked loop chip U1 and a resistor capacitor network) form a pulse generator.

In FIG. 7b, INH is a voltage waveform (controlled by an input/output port PO.1 of the microcontroller U4) of a port INH of the chip U1, PCBᵢₙ is an input voltage waveform (Le. an output VOCₒᵤₜ signal of a VOC unit) of a phase comparator 1 of U1, PCAᵢₙ is an input voltage waveform (i.e. an output clock signal of a timer 1 of the microcontroller U4) of the phase comparator 1, PC1ₒᵤₜ is an output voltage waveform of the phase comparator 1 of U1. Time period A represents mat the resonant ignition means is in a standby state (i.e. a phase during which the gates of the four MOSFET transistors Q3, Q4, Q5 and Q6 of the rail-bridge converter have no driving clock), and time period B represents a resonant ignition phase (i.e. a phase during which the gate driving clock signal of the four MOSFET transistors Q3, Q4, Q5 and Q6 of the full-bridge converter is controlled by DAC of the microcontroller U4), and time period C represents a software clock synchronization phase (i.e. a phase during which the gate driving clock signal of the four MOSFET transistors Q3, Q4, Q5 and Q6 of the full-bridge converter is controlled by the timer 1 of the microcontroller U4).

According to FIG. 8, the main portions of the resonant circuit in the present utility model will be further explained as follows:

The microcontroller U4 is a single chip microcontroller. An output port (e.g, pin 2 DAC0) of the digital-to-analog converter DAC of the single chip microcontroller outputs a voltage controlled signal which is filtered by a capacitor C9 and then delivered to a positive input terminal (11) of an operation amplifier U5 serving as a positive follower. An output terminal (12) of the operation amplifier U5 is directly connected with a negative input terminal to form a positive follower. A voltage signal at the terminal (12) is delivered to the input terminal VCOᵢₙ (Pin 9 of the phase-locked loop chip) of the chip U1 (MC10406) after the action of a RC low-pass filter, r1 and C1 constitute said RC low-pass filter, r2 is connected between port R1 (pin 11) of the chip U1 and the ground, R3 is connected between port R2 (pin 12) of the chip U1 and the ground, and r2 and R3 serve as dock resistors. Clock capacitor C2 is connected between ports 6 and 7 of the chip U1. Pin 3 and pin 4 of the chip U1 are directly connected. Capacitor C3 is connected between pin 16 of the chip U1 and the ground serving as a decoupling capacitor. A clock output port (4) of the chip internal integrated Timer 1 of the microcontroller U4 is directly connected to the port PCAᵢₙ (pin 14 of U1) of the chip U1.

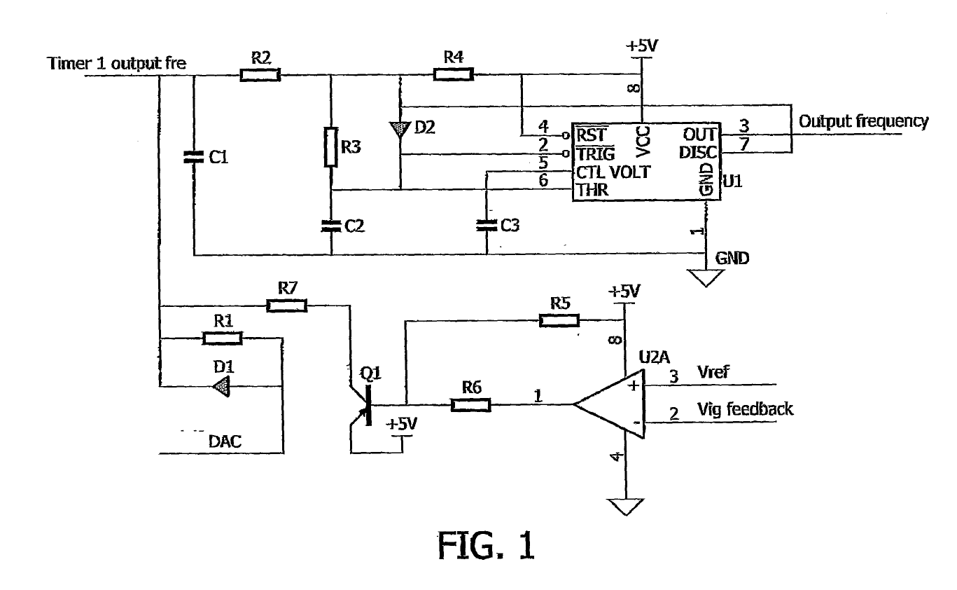

The resonant voltage sampling circuit A and the full-bridge driving circuit B are schematically shown in the form of block diagrams in FIG. 8. This is because that the circuits are well known in the present art and there is no need to describe details thereof (just as they are shown in block diagrams in FIG. 1 when explaining a circuit schematic diagram of an electronic ballast in the prior art) in the present application. Referring to FIGS. 7 and 8, the basic operating principle of VCO of MC14046 will be described as follows:

### (1) Phase A

The I/O port (e.g. PO.1) of the microcontroller U4 is set high, i.e. INH is a high level, the voltage controlled oscillator function of the VCO unit of the chip U1 is inhibited, and no pulse is output from VCOₒᵤₜ (be constantly a low level), At (his time, the Timer 1 is constantly a low level. The result of an exclusive-OR logical operation of signal VCOₒᵤₜ (PCBᵢₙ) and signal Timer 1 (PCAᵢₙ) is constantly a low level. Therefore, no clock signal is input to the full-bridge driving circuit in FIG. 8. MOSFET transistors Q3˜Q6 are switched off, and the whole resonant circuit does not operate.

### (2) Phase B

The I/O port (e.g. PO.1) of the microcontroller U4 is set low, i.e. the INH port of U1 is a low level so as to enable the voltage controlled oscillator function of the VCO unit of the chip U1. DAC (e.g. port DAC0) of the microcontroller U4 decreases from +5V, and accordingly the output pulse frequency of the VCO output port VCOₒᵤₜ of U1 varies from high to low. The scanning frequency procedure starts, and the whole resonant circuit begins to operate. During phase B, Timer 1 (PCAᵢₙ) continues to be maintained at a low level fn the case that PCAᵢₙ of U1 is constantly low, the PC1ₒᵤₜ pulse signal of point(3) follows the PCBᵢₙ pulse clock of point (6), at which time the PC1ₒᵤₜ pulse clock is controlled by the DAC output of the microcontroller U4, During phase B, the VCO unit serves as a traditional voltage controlled oscillator.

### (3) Phase C

The I/O port (e.g. PO.1) of the microcontroller U4 is set high, i.e. the INH port of U1 is a high level, the voltage controlled oscillator function of the VCO unit of the chip U1 is inhibited, no pulse is output from VCOₒᵤₜ, and VCOₒᵤₜ is constantly a low level. The internal timer 1 (Timer 1) of the microcontroller U4 begins to output pulse clock. During phase C, the VCO unit does not serve as a traditional voltage controlled oscillator, but it carries out a NOT gate logic operation function on the signal INH of input port 5 of the chip U1. Specifically, the VCO unit converts a high level signal of INH into a low level signal of VCOₒᵤₜ to control the exclusive-OR logic operation of the phase comparator 1. In other words, in the case that PCBᵢₙ (i.e. VCOₒᵤₜ) is constantly low, the PC1ₒᵤₜ pulse signal of point (3) follows the PCAᵢₙ pulse clock of paint (4).

As is clear from the procedure A-B-C, compared with the function of a traditional phase-locked loop, the features of novel application developed from phase-locked loop chip U1 according to the present utility model are following:

\textcircled{1} the digital phase error signal (i.e. the PC1ₒᵤₜ pulse of point(13)) output from the phase error comparator 1 directly servos as a clock signal required for the operation of the resonant circuit, other than passing through the low-pass filter and then serving as the control voltage of the VCO unit, i.e. being used for phase lock, as shown in FIG. 6a which depicts the prior art.

\textcircled{2} the transition of different frequencies of pulse clock from phase B to phase C is achieved based on the action of the exclusive-OR logic operation of the phase error comparator 1 and by controlling the pin 5 INH signal and the pin 14 PCAᵢₙ signal of the chip U1. Therefore, the present utility model transits output frequency by using internal hardware resources of the phase-looked loop chip U1 without increasing any additional hardware (e.g. an exclusive-OR logic gate) and a dedicated I/O port of the microcontroller U4 (the microcontroller U4 of the present utility model has no other available I/O port). This greatly simplifies the circuit structure and reduces the product, cost.

\textcircled{3} The built-in VCO unit of the chip MC14046 serves as a voltage controlled oscillator function during phase B and carries out a NOT gate; function on the INH signal of pin 5 of the chip during phase C. FIG. 9 is a waveform view of stable ignition voltage of the present utility model, wherein curve 1 is a waveform of an ignition voltage between two ends (9) and (10) of the lamp tube T1 and curve 2 is an amplified waveform view thereof.

Further, the present utility model can solve the problem of insufficient over-voltage protection of the circuit in the prior art. Hereinafter, the over-voltage protective circuit will be explained.

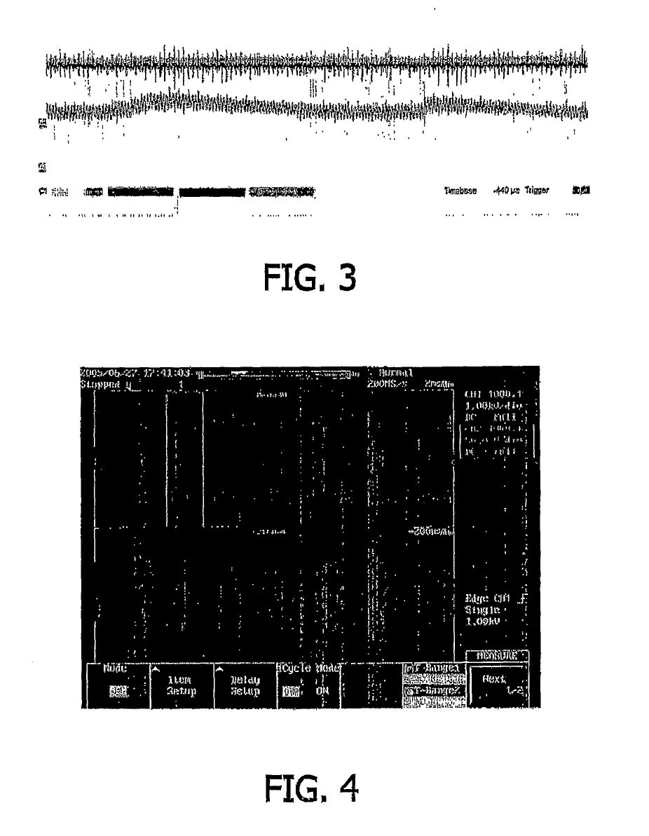

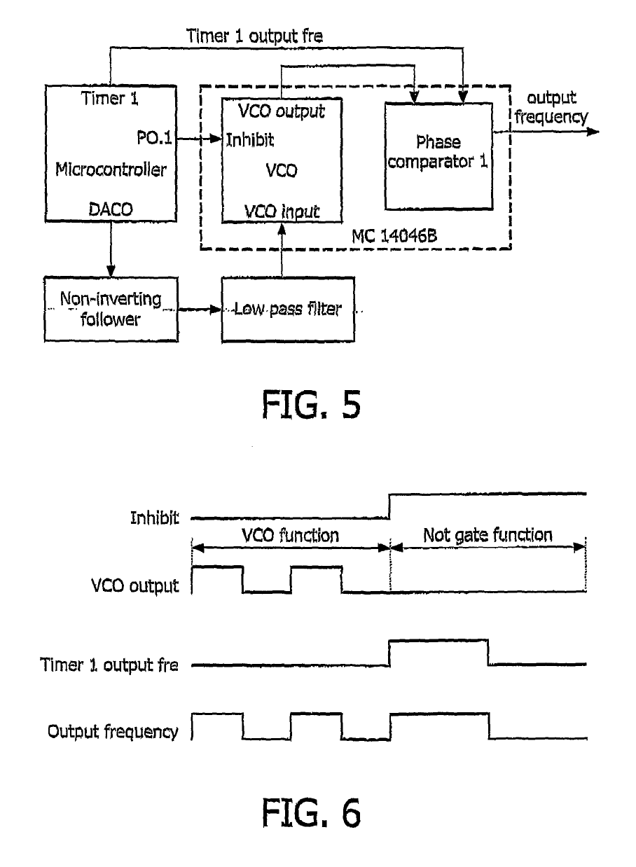

As shown in FIG. 2, the comparator U2 and the resistors R12, R7, R8, R10, R6, C4 and Q1 farm a resonant voltage over-voltage protective circuit. When the resonant voltage is too high, the output terminal (2) of comparator U2 turns to a low level. The transistor Q1 is switched on, and a voltage at two ends of the capacitor C1 increases (the scale of increment relies on the resistances of R1 and R6). As a result, the output pulse clock frequency of the 555 pulse generator increases, and the resonant voltage decreases, thereby achieving the object of over-voltage protection. R10 and R12 provide a voltage reference, by adjusting which, a protective threshold of the resonant voltage can be set. However, the aforesaid over-voltage protection action in the existing resonant ignition means is slow and unstable. After the transistor Q1 is switched on, the +5V power supply slowly charges C1 via the resistor R6. The slow charge procedure results in a large phase delay. In FIG. 3, 1 is a voltage of the output terminal (2) of the comparator U2, 2 is a resonant voltage sampling signal of an point (8), 3 is a reference signal of an point (7), and 4 is a voltage at two ends of the capacitor C1. As is clear from FIG. 3, there is a time lag of about dozens of microseconds from the output terminal (2) voltage of the comparator U2 turning to the low level to the decreasing of the resonant voltage sampling signal 2 at the point (8). Therefore the response speed of over-voltage protection is not fast enough. Ultimately, in the case of a too high resonant voltage, the circuit can not be protected fast and effectively and the resonant circuit is susceptible to damage.

Moreover, since the comparator U2 is not designed with any hysteresis voltage, the level at the output terminal (2) of the comparator U2 is susceptible to oscillation (as shown by curve 1 in FIG. 3), which will result in ignition voltage drift. Additionally, due to lack of a self look function upon the output terminal (2) of U2 turning to the low level, the following procedure will occur repeatedly: detecting the resonant voltage is too high−>the output terminal (2) of U2 turning to the low level−>the voltage at two ends of C1 increasing−>the output pulse clock frequency of VCO increasing−>the resonant voltage decreasing−>the output terminal (2) of U2 turning to the high level−>the voltage of C1 decreasing−>the pulse clock frequency of VCO decreasing−>the resonant voltage increasing−> . . . Ultimately, high ignition voltage peaks out of control will appear continually (as shown in FIG. 4), which impacts the security of the electronic ballast. Curve 1 in FIG. 4 is a waveform of over-high ignition voltage occurring repeatedly without self-lock over-voltage protection in the prior art, and curve 2 is an amplified waveform thereof.

As shown in FIG. 8, the resistors R10 and R12 are serially connected between the +5V power supply and the ground, whose middle serial-connection point is connected with the positive input terminal of the comparator U2, The threshold voltage of the over-voltage protection action can be adjusted by adjusting R10 or R12.

C4 and R11 are serially connected between the point (7) and the ground, and R11 is used for limiting the current peak value at the moment when D1 is switched on, D1 and R9 connected in series provide a positive feedback branch of the comparator U2 to generate a hysteresis voltage. R7 is connected between the point (2) and the base of Q1. R8 is connected between the +5V power supply and the base of Q1. R6 is connected between the emitter of Q1 and the base of Q2. And R4 is connected between the collector of Q2 and pin 12 of the chip U1.

The operating principle of the over-voltage protective circuit is explained as follows,

When the ignition voltage is too high, the sampling voltage at the point (8) is larger than the voltage reference at the point (7), the output level of the comparator U2 jumps down, the transistors Q1 and Q2 are switched on successively, and the resistor R4 is connected in parallel between two ends of R3 via Q2. As a result, the output pulse frequency of VCO increases rapidly, and the resonant voltage decreases rapidly, thereby achieving over-voltage protection, just as shown in FIG. 10. In FIG. 10, waveform 1 is a waveform of ignition voltage at the two ends (9) and (10) of the lamp tube T1 under over-voltage protection, 2 is an amplified waveform view thereof.

Under over-voltage protection, relevant waveforms of the comparator U2 are as shown in FIG. 11. FIG. 11 is a waveform view of relevant voltage under over-voltage protection action, wherein 1 is a signal of the output terminal (point (2)) of the comparator U2, 2 is a reference signal of the positive input terminal (point (7)) of the comparator U2, and 3 is a sampling signal at the negative input terminal (point (8)) of the comparator U2.

In the present utility model, the resistance of resistor R9 is specially designed to ho much smaller than that of R10 and R12. For example, preferably, the resistance of R9 is in a range between 22 and 220Ω, and the resistance of R10 and R12 is in a range between 1KΩ and 10KΩ. Therefore, when the output terminal of the comparator U2 jumps down, the diode D1 is immediately switched on, and the small resistance of resistor R9 pulls down the reference electric potential at me point (7), thereby forming positive feedback. The reference electric potential decreases on a large scale (e.g, 2.7V) due to positive feedback. In this manner, even if the ignition voltage decreases after the action of the high voltage protection circuit, the sampling voltage is still-high than the voltage reference, the jumped down level at the output terminal of the comparator U2 is self locked, thereby achieving self lock of an over-voltage protection state. Therefore, the resonant circuit has the security improved in the case of over voltage. This self-looked technical solution can achieve self lock of an over-voltage protection state simply by adding a diode (D1) and a resister (R9) without the need to design a dedicated self lock circuit. Therefore, the circuit is of a simple structure and has a low cost. Upon detection of the fact that the actual resonant voltage is lower than the protective threshold voltage, the output terminal of U2 is a high level, D1 is switched off to prevent switching Q1 on and thereby triggering the high voltage protection action.

As is clear from FIG. 11, after the level signal of the output terminal (point (2)) of the comparator U2 jumps down, the sampling signal at the negative input terminal (point (8)) of the comparator U2 decreases quickly. Compared with the 555 VCO in the prior art, the present utility model does not have the procedure of slowly charging the capacitor during the over-voltage protection action. Therefore, the over-voltage protection action is much faster than that in the prior art.

In short, the novel features of the present utility model include: skillfully designing the circuit, making full use of the existing hardware resources, achieves control of frequency transition during different phases and self look function of over-voltage protection action with the least hardware resources (least electronic elements/devices and microcontroller I/O ports). Furthermore, the present utility model almost does not increase the cost of hardware while greatly improving the performance (mainly including the resonant voltage stability and over-voltage protection).

The present utility model can be widely applied to electronic ballasts of UHP, HID, and gas discharge lamps such as UHP and HID.

For the present utility model, the described embodiments are merely illustrative and not restrictive. As the present utility model has been described with reference to the embodiments, it is to be understood by those skilled in the art that modifications or equivalents made within the spirit and scope of the present utility model fall within the protection scope of the present utility model.

In the claims of the present utility model, the word “comprising” and its equivalents do not exclude other components, and the word “a” or “an” does not exclude the existence of a plurality of such components.

1. An impulse generator for driving an electronic ballast, said electronic ballast comprising a resonance ignition circuit, characterized in that said impulse generator comprises: a micro-controller for generating a clock frequency signal, a logical time sequence control signal and a control voltage signal; a voltage controlled oscillator, coupled to said micro-controller, for receiving said logical time sequence control signal and said control voltage signal to generate oscillation and output a voltage controlled oscillating frequency signal; a phase comparator, coupled to said voltage controlled oscillator, for receiving said clock frequency signal and said voltage controlled oscillating frequency signal to perform, a logical exclusive-OR operation and output an impulse signal of corresponding frequency, thereby driving said resonance ignition circuit to generate a resonance voltage.

2. The impulse generator as recited in claim 1, characterized in that said impulse generator further includes a non-inverting follower, coupled to said micro-controller, for enhancing said control voltage signal.

3. The impulse generator as recited in claim 2, characterized in that said impulse generator further includes a low pass filter, coupled between said non-inverting follower and said voltage controlled oscillator, for filtering out the high frequency component in said control voltage signal to preclude interference on said voltage controlled oscillator.

4. The impulse generator as recited in claim 1, characterized in that said voltage controlled oscillator and said phase comparator belong to different functional units of the same integrated phase-locked loop chip, respectively.

5. The impulse generator as recited in claim 1, characterised in that an output pin for said voltage controlled oscillator of said voltage controlled oscillator is directly connected to one input pin for said phase comparator; the other input pin of said phase comparator is directly connected to a clock output port of timer of said micro-controller; said impulse signal is output from the output pin of said phase comparator.

6. An electronic ballast, comprising said impulse generator as recited in claim 1.

7. The electronic ballast as recited in claim 6, comprising: a full bridge drive circuit, coupled to said impulse generator, for outputting a drive signal in accordance with said pulse clock signal; a full bridge converter, coupled to said full bridge drive circuit, for converting a DC bus voltage into a square wave voltage having alternately positive and negative polarities in accordance with said drive signal and outputting it; a LC series resonance circuit, coupled to said full bridge converter, for generating a resonance voltage applied to a load by using a high frequency resonance in accordance with said alternating square wave voltage; a resonance voltage sampling circuit, coupled to said LC series resonance circuit, for sampling said resonance voltage; an over-voltage protection circuit, coupled to said resonance voltage sampling, circuit and said impulse generator, for providing an over-voltage protection to resonance voltage; a resonance voltage detecting circuit, coupled to said resonance voltage sampling circuit, over-voltage protection circuit and impulse generator, for detecting whether said resonance voltage reaches a setting value during the procedure of frequency scanning of said pulse clock signal.

8. The electronic ballast as recited in claim 7, characterized in that said over-voltage protection circuit comprises: a voltage comparator, the non-inverting input thereof being connected to a reference voltage with a special value, and the inverting input thereof being connected to a sampling voltage, said sampling voltage being connected to said resonance voltage sampling circuit and varying in proportion to the circuit resonance voltage, the voltage comparator outputting a reference signal and being used to adjust said resonance voltage to accordance with said reference signal; a diode, the anode of said diode being connected to the non-inverting of said voltage comparator, the cathode of said diode being connected to the output of said voltage comparator via a resistor, for forming a positive feedback function on said voltage comparator.

9. The electronic ballast as recited in claim 7, characterized in that said over-voltage protection circuit comprises: a voltage comparator, a diode and a first resistor that are connected in series between the non-inverting input and the output of said voltage comparator, and a second resistor connected between the non-inverting input of the voltage comparator and power supply voltage terminal, and a third resistor connected between the non-inverting input of the comparator and ground, wherein the anode of said diode is connected to the positive input of said voltage comparator, the positions of said diode and first resistor can be exchanged.

10. A gas discharge lamp, comprising said electronic ballast as recited in claim 6.
